(19) United States
(12) Patent Application Publication
(10) Pub. No.: US 2025/0189350 A1
(43) Pub. Date: Jun. 12, 2025

(54) MULTI-AXIS OPERATION APPARATUS IN ISOTROPIC ARRANGEMENT

(71) Applicant: GALLANT MICRO. MACHINING CO., LTD., New Taipei City (TW)

(72) Inventors: TUN-CHIH SHIH, NEW TAIPEI CITY (TW); WEI-HAN KAO, New Taipei City (TW); YI-KAI TSENG, NEW TAIPEI CITY (TW)

(21) Appl. No.: 18/900,857

(22) Filed: Sep. 29, 2024

(30) Foreign Application Priority Data
Dec. 8, 2023 (TW) 112147814

(51) Int. Cl. G01D 5/347; H01L 21/68; H01L 21/683

(52) U.S. Cl. CPC G01D 5/34715; H01L 21/681; H01L 21/683

(57) ABSTRACT

A multi-axis operation apparatus in an isotropic arrangement includes a carrying device, a plurality of two-dimensional scale regions, and an operating mechanism. The carrying device includes a moving mechanism and a carrying platform. The operating mechanism includes a working member and a plurality of position sensors. When the multi-axis operation apparatus is operated to perform a predetermined process, the operating mechanism confirms a real-time position of a target object from the two-dimensional scale regions through the position sensors, such that the working member is configured to perform a predetermined step toward a predetermined area of the target object along an interval direction according to the real-time position.

### CROSS-REFERENCE TO RELATED PATENT APPLICATION

This application claims the benefit of priority to Taiwan Patent Application No. 112147814, filed on Dec. 8, 2023. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an operation apparatus, and more particularly to a multi-axis operation apparatus in an isotropic arrangement.

### BACKGROUND OF THE DISCLOSURE

As the structure of an electronic product becomes more and more complex, various components need to meet increasingly higher precision requirements during the manufacturing process. As a result, in order to perform relevant operations, a conventional operation apparatus needs to accurately identify the location of the components. That is to say, the conventional operation apparatus also needs to meet increasingly higher precision requirements.

### SUMMARY OF THE DISCLOSURE

In response to the above-referenced technical inadequacy, the present disclosure provides a multi-axis operation apparatus in an isotropic arrangement that can effectively improve on issues in a conventional operation apparatus.

In order to solve the above-mentioned problem, one of the technical aspects adopted by the present disclosure is to provide a multi-axis operation apparatus in an isotropic arrangement. The multi-axis operation apparatus includes a carrying device, a plurality of two-dimensional scale regions, and an operating mechanism. The carrying device includes a moving mechanism and a carrying platform. The moving mechanism is movable along a first direction and a second direction that is perpendicular to the first direction. The carrying platform has a target region that is configured for placement of a target object. The carrying platform is installed on the moving mechanism, such that the carrying platform is movable in a displacement plane jointly defined by the first direction and the second direction through the moving mechanism. The two-dimensional scale regions are located on the carrying platform, and the two-dimensional scale regions are configured to be parallel to the target object or the target region and to be arranged at an outer side of the target region. The operating mechanism is spaced apart from the carrying platform along an interval direction that is perpendicular to the displacement plane, and the operating mechanism includes a working member and a plurality of position sensors. The working member is configured to face toward the target object or the target region along the interval direction. The position sensors respectively face toward the two-dimensional scale regions along the interval direction. When the multi-axis operation apparatus is operated to perform a predetermined operation, the operating mechanism confirms a real-time position of the target object from the two-dimensional scale regions through the position sensors, such that the working member performs a predetermined process on a predetermined area of the target object along the interval direction according to the real-time position.

Therefore, in the multi-axis operation apparatus provided by the present disclosure, the two-dimensional scale regions are arranged relative to the target object (or the target region) and cooperate respectively with the position sensors, such that the multi-axis operation apparatus can accurately confirm the real-time position of the target object, thereby facilitating the working member to accurately perform the predetermined process on the predetermined area of the target object.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a multi-axis operation apparatus in an isotropic arrangement according to a first embodiment of the present disclosure;

FIG. 2 is a schematic side view of FIG. 1;

FIG. 3 is a schematic top view of FIG. 1;

FIG. 4 is a schematic top view showing an arrangement of two-dimensional scale regions and a target object;

FIG. 5 is a schematic perspective view showing a subsequent action of the multi-axis operation apparatus of FIG. 1;

FIG. 6 is a schematic perspective view showing a subsequent action of the multi-axis operation apparatus of FIG. 5;

FIG. 7 is a schematic perspective view of a multi-axis operation apparatus in an isotropic arrangement according to a second embodiment of the present disclosure;

FIG. 8 is a schematic side view of FIG. 7;

FIG. 9 is a schematic view showing a subsequent action of the multi-axis operation apparatus of FIG. 8; and

FIG. 10 is a schematic view showing a subsequent action of the multi-axis operation apparatus of FIG. 9.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

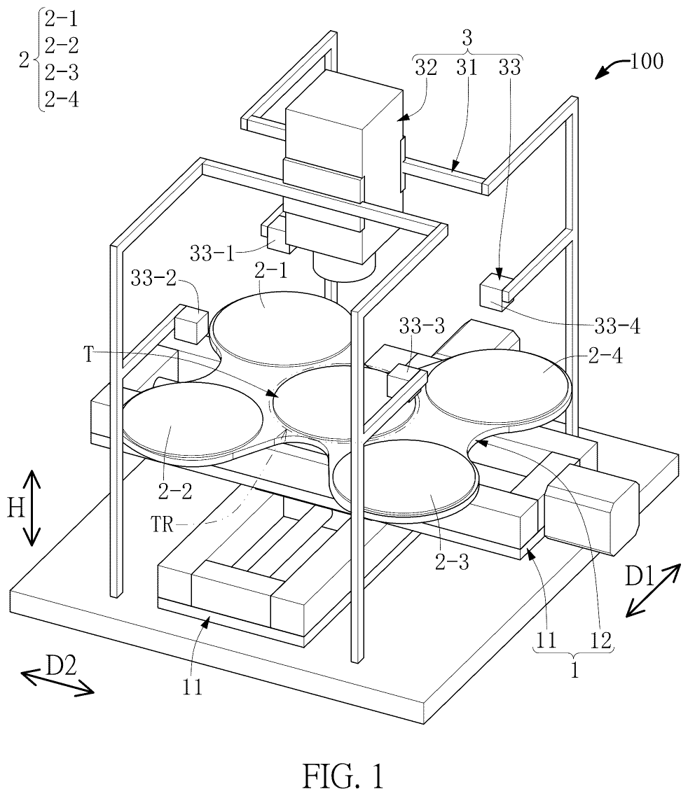

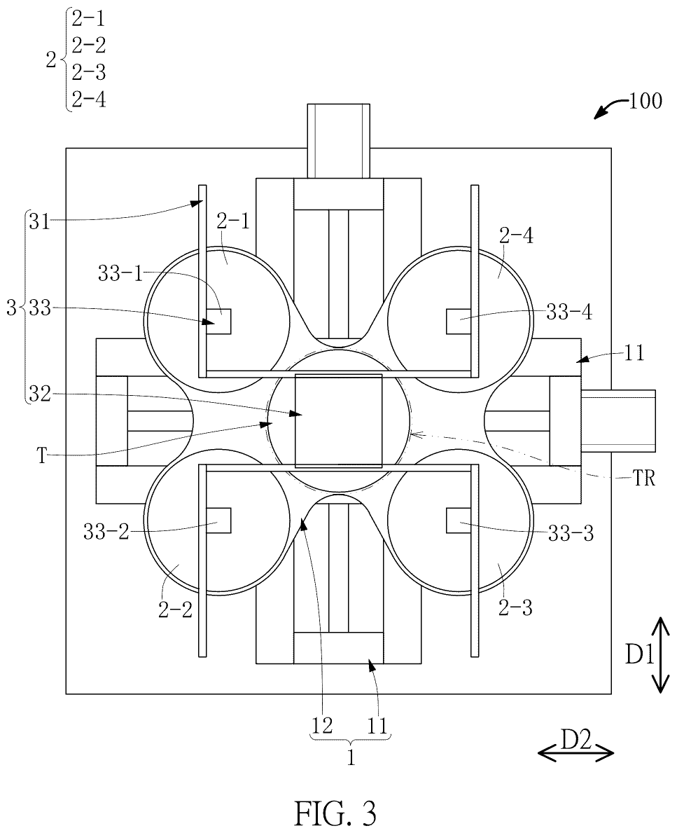

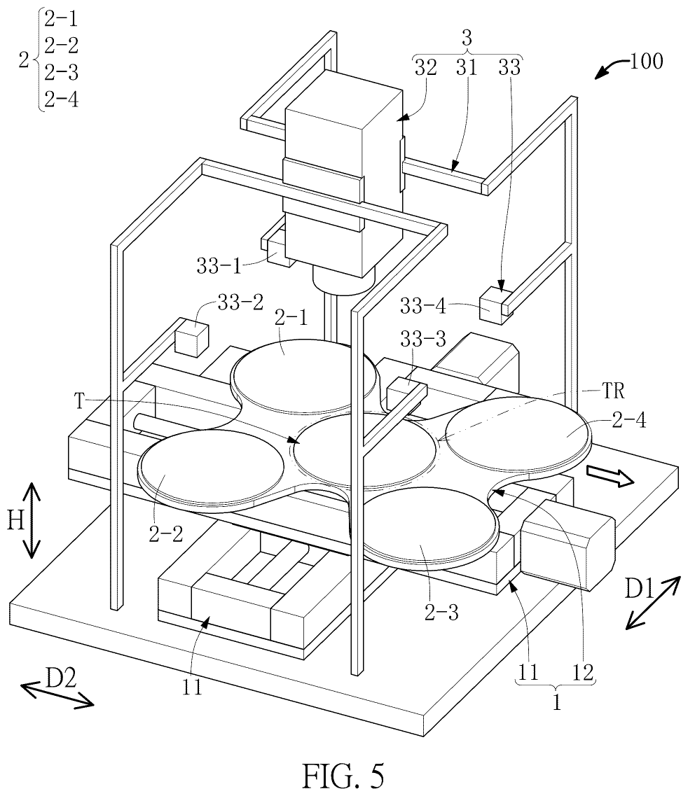

Referring to FIG. 1 to FIG. 6, a first embodiment of the present disclosure is provided. As shown in FIG. 1 to FIG. 3, the present embodiment provides a multi-axis operation apparatus in an isotropic arrangement 100 (hereunder referred to as the multi-axis operation apparatus 100), which can be used to perform a predetermined process. The predetermined process can be adjusted and changed according to design requirements. For example, in the drawings of present embodiment, the multi-axis operation apparatus 100 is exemplified as performing a detection operation. However, in other embodiments of the present disclosure (not shown in the drawings), the multi-axis operation apparatus 100 can also be used to perform a chip picking operation, a chip placement operation, or a chip bonding operation according to the design requirements.

The multi-axis operation apparatus 100 includes a carrying device 1, a plurality of two-dimensional scale regions 2 that are located on the carrying device 1, and an operating mechanism 3 that is spaced apart from the carrying device 1 along an interval direction H. In the present embodiment, the interval direction H is a vertical direction, but the present disclosure is not limited thereto.

It should be noted that, in order to facilitate understanding of the present embodiment, the drawings of the present embodiment only show a partial structure of the multi-axis operation apparatus 100. In this way, the structure and connection relationship of each component of the multi-axis operation apparatus 100 can be clearly illustrated. However, the present disclosure is not limited to these drawings. The structure and the connection relationship of each component of the multi-axis operation apparatus 100 in the present embodiment will be described below.

As shown in FIG. 1 to FIG. 4, the carrying device 1 includes a moving mechanism 11 and a carrying platform 12 that is installed on the moving mechanism 11. In order to facilitate description of the structure of the following components provided by the present embodiment, a moving direction of the moving mechanism 11 defines a first direction D1 and a second direction D2 that are perpendicular to the interval direction H and to each other, and the first direction D1 and the second direction D2 can jointly define a displacement plane that is perpendicular to the interval direction H. That is to say, the moving mechanism 11 is movable along the first direction D1 and the second direction D2 that is perpendicular to the first direction D1, but the present disclosure is not limited thereto. For example, in other embodiments of the present disclosure (not shown in the drawings), the first direction D1 and the second direction D2 can be irrelevant to the moving direction of the moving mechanism 11. In the present embodiment, the moving mechanism 11 is, for example, an X-Y axis moving platform or an air-bearing position moving platform.

The carrying platform 12 has a target region TR that is configured for providing the target object T to be disposed thereon. The carrying platform 12 is installed on the moving mechanism 11, such that the carrying platform 12 is movable in the displacement plane through the moving mechanism 11. That is to say, in the present embodiment, the moving mechanism 11 cannot rotate the carrying platform 12 and cannot move the carrying platform 12 along the interval direction H, but the present disclosure is not limited thereto. For example, in other embodiments of the present disclosure (not shown in the drawings), the moving mechanism 11 can adopt a structure that is capable of rotating the carrying platform 12 or moving the carrying platform 12 along the interval direction H according to the design requirements.

The two-dimensional scale regions 2 are spaced apart from each other, and are arranged on the carrying platform 12. In addition, the two-dimensional scale regions 2 are configured to be parallel to the target object T (or the target region TR). A size of each of the two-dimensional scale regions 2 is configured to be greater than or equal to a size of the target object T (or the target region TR). In the present embodiment, each of the two-dimensional scale regions 2 is a two-dimensional encoder, and an outer contour of each of the two-dimensional scale regions 2 is preferably equal to an outer contour of the target object T (or the target region TR), such that the operating mechanism 3 can confirm a real-time position of the target object T through the two-dimensional scale regions 2, but the present disclosure is not limited thereto.

Specifically, in the present embodiment, a quantity of the two-dimensional scale regions 2 is four, and these four two-dimensional scale regions 2 are respectively named as a first scale region 2-1, a second scale region 2-2, a third scale region 2-3, and a fourth scale region 2-4. However, the present disclosure is not limited thereto. For example, in other embodiments of the present disclosure (not shown in the drawings), the quantity of the two-dimensional scale regions 2 can also be two or three.

The first scale region 2-1, the second scale region 2-2, the third scale region 2-3, and the fourth scale region 2-4 are located on the carrying platform 12, and are parallel to the target object T (or the target region TR). As such, the first scale region 2-1, the second scale region 2-2, the third scale region 2-3, and the fourth scale region 2-4 are preferably located on a same plane. That is to say, an outer surface of the target object T (or the target region TR) can be coplanar with the two-dimensional scale regions 2, and is parallel to the displacement plane.

In addition, a size of the first scale region 2-1, a size of the second scale region 2-2, a size of the third scale region 2-3, and a size of the fourth scale region 2-4 are equal to each other, so as to ensure that the real-time position of the target object T can be confirmed through the two-dimensional scale regions 2 when the carrying platform 12 moves to any position in the displacement plane.

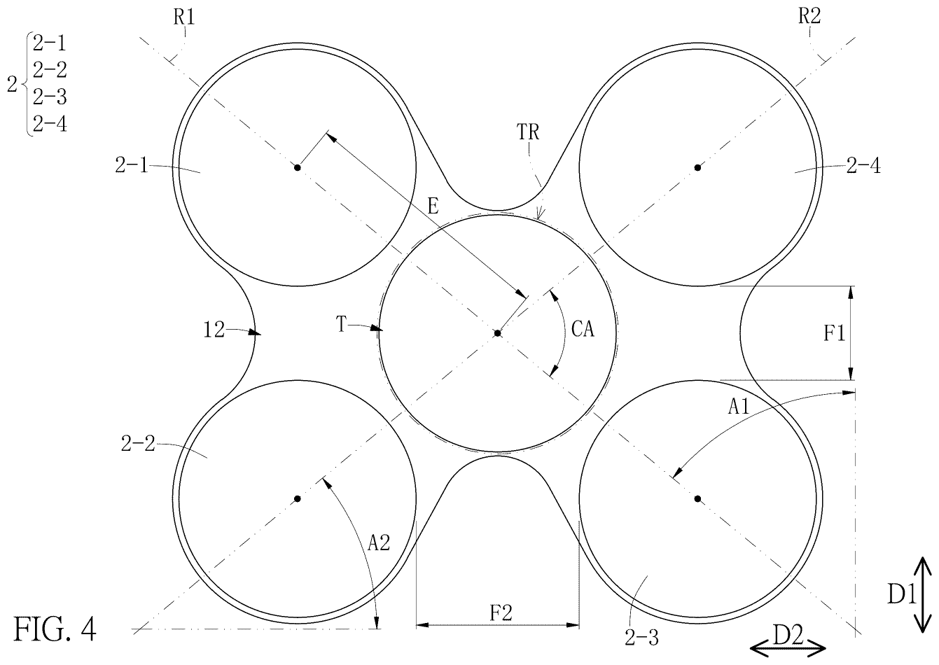

As shown in FIG. 1 and FIG. 4, the two-dimensional scale regions 2 are arranged at an outside of the target object T (or the target region TR), and the two-dimensional scale regions 2 are spaced apart from the target object T (or the target region TR) by a same interval. Specifically, a center of each of the two-dimensional scale regions 2 is configured to be spaced apart from a center of the target object T (or the target region TR) by one of arrangement distances E, and the arrangement distances E respectively corresponding to the two-dimensional scale regions 2 are equal to each other. That is to say, the arrangement distances E defined between the center of the target object T (or the target region TR) and each of a center of the first scale region 2-1, a center of the second scale region 2-2, a center of the third scale region 2-3, and a center of the fourth scale region 2-4 are the same, which is beneficial for quick confirmation of the real-time position of the target object T through the two-dimensional scale regions 2. However, the present disclosure is not limited thereto. For example, in other embodiments of the present disclosure (not shown in the drawings), a shortest distance between an edge of each of the two-dimensional scale regions 2 and an edge of the target object T can be arranged to be the same.

Furthermore, in the present embodiment, any one of the two-dimensional scale regions 2 is spaced apart from another one of the two-dimensional scale regions 2 along the first direction D1 by a first distance F1, and is spaced apart from the other one of the two-dimensional scale regions 2 along the second direction D2 by a second distance F2 that is greater than the first distance F1. More specifically, the first scale region 2-1 and the second scale region 2-2 are arranged along the first direction D1, and are separated from each other by the first distance F1. The first scale region 2-1 and the fourth scale region 2-4 are arranged along the second direction D2, and are separated from each other by the second distance F2.

In the present embodiment, the target object T (or the target region TR) has a circular shape, but the shape of the target object T (or the target region TR) can also be adjusted and changed according to design requirements (e.g., a square shape or a polygonal shape). Furthermore, the centers of two of the two-dimensional scale regions 2 are located on a first radial direction R1 of the target object T (or the target region TR), and the centers of another two of the two-dimensional scale regions 2 are located on a second radial direction R2 of the target object T (or the target region TR). Moreover, an arrangement angle CA between the first radial direction R1 and the second radial direction R2 is within a range from 60 degrees to 120 degrees.

More specifically, the center of the first scale region 2-1, the center of the third scale region 2-3, and the center of the target object T (or the target region TR) are located on the first radial direction R1. The center of the second scale region 2-2, the center of the fourth scale region 2-4, and the center of the target object T (or the target region TR) are located on the second radial direction R2. Accordingly, in the present embodiment, the multi-axis operation apparatus 100 adopts the above-mentioned arrangement of the two-dimensional scale regions 2 for enabling the first scale region 2-1 and the third scale region 2-3 in the first radial direction R1 to cooperate with the second scale region 2-2 and the fourth scale region 2-4 in the second radial direction R2, thereby accurately determining the position of the target object T.

On the other hand, a first angle Al between the first radial direction R1 and the first direction D1 is within a range from 0 degrees to 90 degrees, and a second angle A2 between the second radial direction R2 and the second direction D2 is within a range from 0 degrees to 90 degrees. By arranging the first radial direction R1 and the second radial direction R2 not to be parallel to the first direction D1 and the second direction D2, the multi-axis operation apparatus 100 can have a higher operating accuracy.

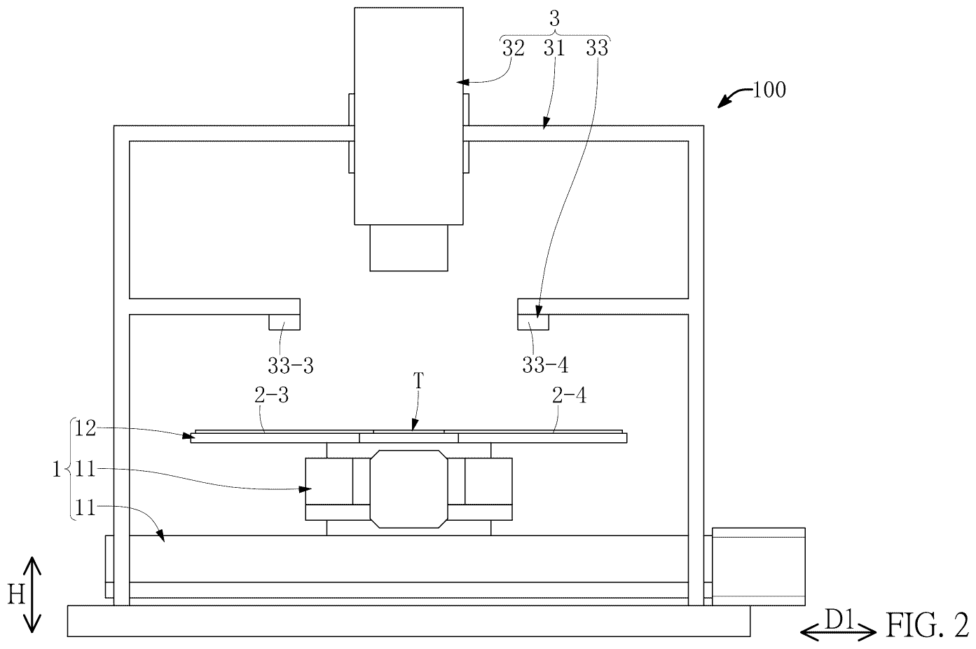

As shown in FIG. 1 and FIG. 2, the operating mechanism 3 includes a bracket 31, a working member 32 that is installed on the bracket 31, and a plurality of position sensors 33 that are installed on the bracket 31 and are separately disposed at an outer side of the working member 32. The working member 32 faces toward the target object T (or the target region TR) along the interval direction H, a quantity of the position sensors 33 is preferably equal to the quantity of the two-dimensional scale regions 2, and the position sensors 33 respectively face toward the two-dimensional scale regions 2 along the interval direction H.

In the present embodiment, the quantity of the position sensors 33 is four, and the position sensors 33 include a first position sensor 33-1, a second position sensor 33-2, a third position sensor 33-3, and a fourth position sensor 33-4. The first position sensor 33-1, the second position sensor 33-2, the third position sensor 33-3, and the fourth position sensor 33-4 respectively face toward the first scale region 2-1, the second scale region 2-2, the third scale region 2-3, and the fourth scale region 2-4, so as to respectively sense the two-dimensional scale regions 2. Accordingly, the operating mechanism 3 can obtain the real-time position of the target object T according to data sensed by the first position sensor 33-1, the second position sensor 33-2, the third position sensor 33-3, and the fourth position sensor 33-4.

When the multi-axis operation apparatus 100 is operated to perform the predetermined process, the carrying platform 12 moves in the displacement plane through the moving mechanism 11, and a projection region defined by orthogonally projecting each of the position sensors 33 onto the carrying platform 12 along the interval direction H is kept on a corresponding one of the two-dimensional scale regions 2. That is to say, the carrying platform 12 freely moves in the displacement plane through the moving mechanism 11, and the projection regions formed by the position sensors 33 correspondingly fall on the two-dimensional scale regions 2. In this way, the target object T is allowed to move to any position, and the multi-axis operation apparatus 100 can still confirm the real-time position of the target object T since the position sensors 33 correspondingly detect the two-dimensional scale regions 2.

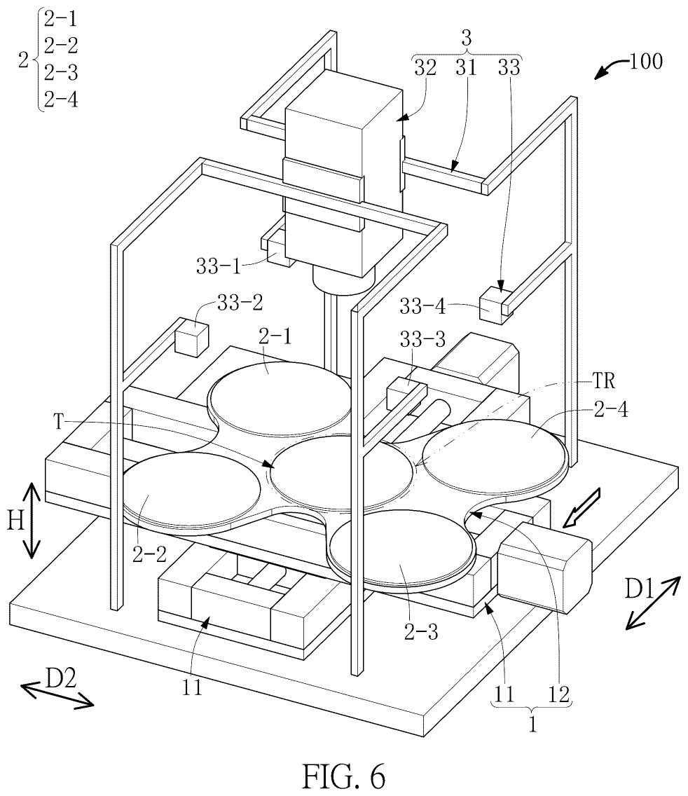

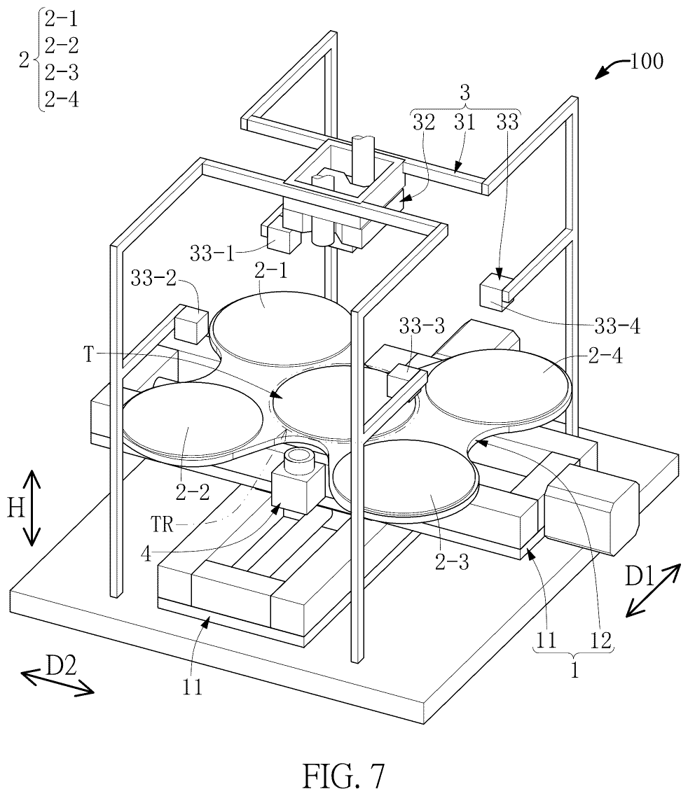

Based on the description above, when the multi-axis operation apparatus 100 is operated to perform the predetermined process (e.g., the detection operation), the operating mechanism 3 confirms the real-time position of the target object T from the two-dimensional scale regions 2 through the position sensors 33, such that the working member 32 is configured to perform a predetermined step (e.g., a process of detecting whether or not the target object T has defects, as shown in FIG. 6 and FIG. 7) toward a predetermined area of the target object T along the interval direction H according to the real-time position.

Accordingly, in the multi-axis operation apparatus 100 of the present disclosure, the two-dimensional scale regions 2 are arranged relative to the target object T (or the target region TR) and cooperate respectively matched with the position sensors 33, such that the multi-axis operation apparatus 100 can accurately confirm the real-time position of the target object T, thereby facilitating the working member 32 to accurately perform the predetermined process on the predetermined area of the target object T.

### Second Embodiment

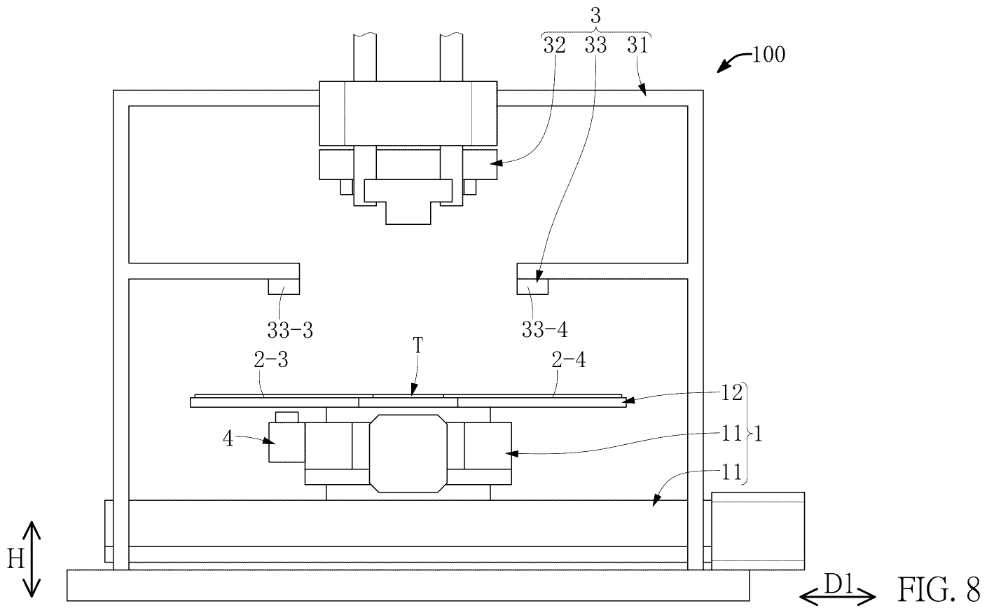

Referring to FIG. 7 to FIG. 10, a second embodiment of the present disclosure is provided. The second embodiment is similar to the first embodiment, and the similarities therebetween will not be reiterated herein. The differences between the first and second embodiments are substantially as follows.

In the present embodiment, the multi-axis operation apparatus 100 in the drawings is exemplified as performing the chip placement operation, but the present disclosure is not limited thereto. The working member 32 is configured to remain stationary along the first direction D1 and the second direction D2, and the working member 32 is configured to absorb a chip C that is transported by an external transfer mechanism O. For example, the working member 32 is a suction nozzle. The external transfer mechanism O includes a picker. The picker picks up the chip C from an external wafer supply station (not shown in the drawings), and moves the chip C below the working component 32 for allowing the working member 32 to pick up the chip C. In addition, the working member 32 is configured to place the chip C onto the predetermined area of the target object T along the interval direction H during the predetermined process.

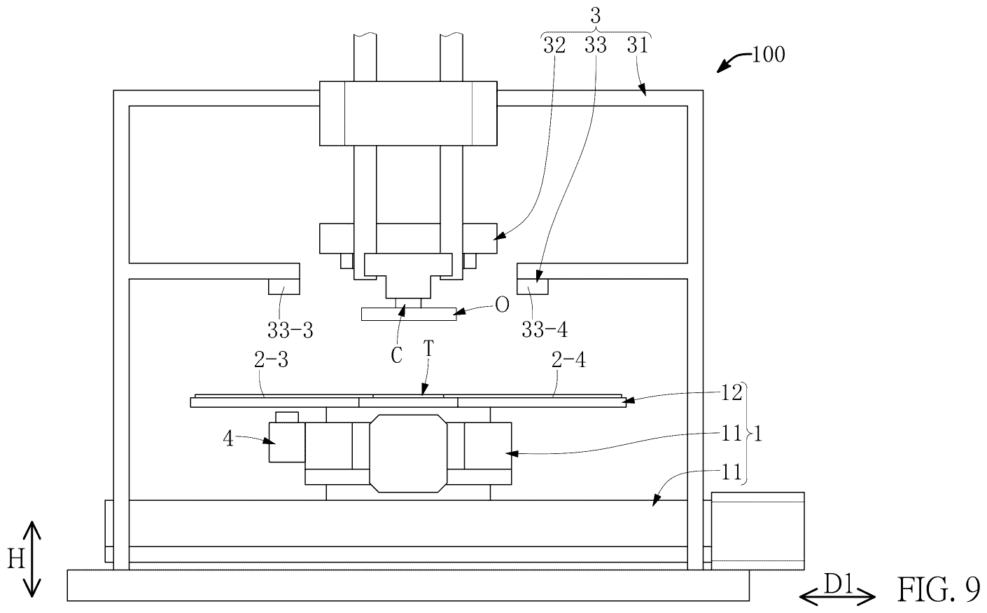

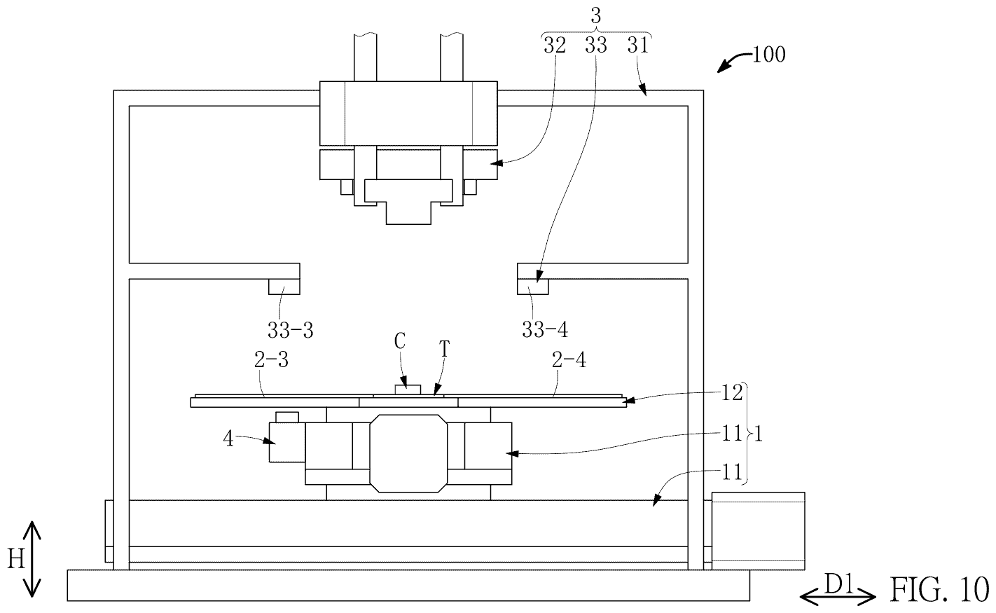

That is to say, in the present embodiment, the two-dimensional scale regions 2 are arranged relative to the target object T and cooperate respectively with the position sensors 33, such that the multi-axis operation apparatus 100 accurately confirms the real-time position of the target object T. Based on the real-time position of the target object T, the working member 32 that adsorbs the chip C from the external transfer mechanism O is able to place the chip C in the predetermined area of the target object T along the interval direction H (as shown in FIG. 9 and FIG. 10), thereby achieving a high-precision chip placement operation.

In the present embodiment, the multi-axis operation apparatus 100 further includes a camera 4. Preferably, an end surface of the camera 4 is coplanar with the two-dimensional scale regions 2. The camera 4 is configured to be arranged adjacent to the target object T, and is located between two of the two-dimensional scale regions 2. In the present embodiment, the carrying platform 12 has a notch formed between any two adjacent ones of the two-dimensional scale regions 2 that are separated by the second distance F2, and the camera 4 is placed in one of the notches. By being located between two adjacent ones of the two-dimensional scale regions 2 that are separated by the second distance F2, the camera 4 can better observe the working member 32 and the chip C adsorbed thereby. However, the present disclosure is not limited thereto. The working member 32 can confirm the position of the adsorbed chip C through the camera 4, thereby ensuring a relative positional accuracy between the working member 32 and the chip C. As such, an improved precision of the chip placement operation can be achieved.

### Beneficial Effects of the Embodiments

In conclusion, in the multi-axis operation apparatus in the isotropic arrangement provided by the present disclosure, the two-dimensional scale regions are arranged relative to the target object (or the target region) and cooperate respectively with the position sensors, such that the multi-axis operation apparatus can accurately confirm the real-time position of the target object, thereby facilitating the working member to accurately perform the predetermined process on the predetermined area of the target object.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A multi-axis operation apparatus in an isotropic arrangement, comprising:
a carrying device including:
a moving mechanism being movable along a first direction and a second direction that is perpendicular to the first direction; and
a carrying platform having a target region that is configured for placement of a target object, wherein the carrying platform is installed on the moving mechanism, such that the carrying platform is movable in a displacement plane jointly defined by the first direction and the second direction through the moving mechanism;
a plurality of two-dimensional scale regions being located on the carrying platform, wherein the two-dimensional scale regions are configured to be parallel to the target object or the target region and to be arranged at an outer side of the target object or the target region; and
an operating mechanism spaced apart from the carrying platform along an interval direction that is perpendicular to the displacement plane, wherein the operating mechanism includes:
a working member configured to face toward the target object or the target region along the interval direction; and
a plurality of position sensors respectively facing toward the two-dimensional scale regions along the interval direction;
wherein, when the multi-axis operation apparatus is operated to perform a predetermined operation, the operating mechanism confirms a real-time position of the target object from the two-dimensional scale regions through the position sensors, such that the working member performs a predetermined process on a predetermined area of the target object along the interval direction according to the real-time position.

2. The multi-axis operation apparatus according to claim 1, wherein, when the multi-axis operation apparatus is operated to perform the predetermined process, the carrying platform moves in the displacement plane, and a projection region defined by orthogonally projecting each of the position sensors onto the carrying platform along the interval direction remains located on a corresponding one of the two-dimensional scale regions.

3. The multi-axis operation apparatus according to claim 1, wherein a size of each of the two-dimensional scale regions is configured to be greater than or equal to a size of the target object or the target region, an outer surface of the target object is coplanar with the two-dimensional scale regions and is parallel to the displacement plane, and the two-dimensional scale regions are spaced apart from the target object by a same interval.

4. The multi-axis operation apparatus according to claim 1, wherein each of the two-dimensional scale regions is a two-dimensional encoder, and an outer contour of each of the two-dimensional scale regions is configured to be equal to an outer contour of the target object or the target region.

5. The multi-axis operation apparatus according to claim 1, wherein an arrangement distance is defined between a center of each of the two-dimensional scale regions and a center of the target object or the target region, and the arrangement distances that respectively correspond to the two-dimensional scale regions are equal to each other.

6. The multi-axis operation apparatus according to claim 5, wherein a quantity of the two-dimensional scale regions is four; wherein any one of the two-dimensional scale regions is spaced apart from another one of the two-dimensional scale regions along the first direction by a first distance, and is spaced apart from yet another one of the two-dimensional scale regions along the second direction by a second distance that is greater than the first distance.

7. The multi-axis operation apparatus according to claim 5, wherein the target object or the target region has a circular shape, and a quantity of the two-dimensional scale regions is four; wherein the centers of two of the two-dimensional scale regions are located on a first radial direction of the target object or the target region, and the centers of another two of the two-dimensional scale regions are located on a second radial direction of the target object; wherein an arrangement angle between the first radial direction and the second radial direction is within a range from 60 degrees to 120 degrees.

8. The multi-axis operation apparatus according to claim 7, wherein an angle between the first radial direction and the first direction is within a range from 0 degrees to 90 degrees.

9. The multi-axis operation apparatus according to claim 1, wherein the working member is configured to remain stationary along the first direction and the second direction, and the working member is configured to adsorb a chip that is transported by an external transfer mechanism; wherein the working member is configured to place the chip onto the predetermined area of the target object along the interval direction during the predetermined process.

10. The multi-axis operation apparatus according to claim 9, further comprising a camera, wherein an end surface of the camera is coplanar with the two-dimensional scale regions, and the camera is disposed adjacent to the target object and is located between two of the two-dimensional scale regions; wherein the working member is configured to confirm a position of the adsorbed chip through the camera.
